(19) United States
(12) Patent Application Publication
(10) Pub. No.: US 2012/0305986 A1
(43) Pub. Date: Dec. 6, 2012

(54) SEMICONDUCTOR STRUCTURE AND METHOD FOR FORMING THE SAME

(75) Inventors: Jing Wang, Beijing (CN); Lei Guo, Beijing (CN)

(73) Assignee: TSINGHUA UNIVERSITY, Beijing (CN)

(21) Appl. No.: 13/376,442

(22) PCT Filed: Nov. 11, 2011
(86) PCT No.: PCT/CN2011/082109

§ 371 Date: Dec. 6, 2011

(30) Foreign Application Priority Data
Jun. 3, 2011 (CN) 201110149946.0

(51) Int. Cl. H01L 29/16; H01L 21/336

(52) U.S. Cl. 257/183; 438/301; 257/E29.082; 257/E21.409

(57) ABSTRACT

A semiconductor structure and a method for forming the same are provided. The semiconductor structure includes a wafer; a plurality of convex structures formed on the wafer, in which every two adjacent convex structures are separated by a cavity in a predetermined pattern and arranged in an array, and the cavity between every two adjacent convex structures is less than 50 nm in width; and a first semiconductor film formed on the plurality of convex structures, in which a part of the first semiconductor film is spaced apart from the wafer.

### CROSS-REFERENCE TO RELATED APPLICATIONS

The present application is a national phase entry under 35 U.S.C. §371 of International Application No. PCT/CN2011/082109 filed Nov. 11, 2011, published in English, which claims priority from Chinese Application No. 201110149946.0, filed Jun. 3, 2011, all of which are incorporated herein by reference.

### FIELD OF THE INVENTION

The present disclosure relates to a semiconductor manufacture and design, and more particularly to a semiconductor structure and a method for forming the same.

### BACKGROUND OF THE INVENTION

For a long time, in order to achieve a higher chip density, a faster working speed and a lower power consumption, a feature size of a MOSFET (metal-oxide-semiconductor field effect transistor) is continuously scaled down according to Moore's law, and a working speed of the MOSFET is faster and faster. Currently, the feature size of the MOSFET has reached a nanometer level. However, a serious challenge is an emergence of a short-channel effect, such as a subthreshold voltage roll-off (Vₜ roll-off), a DIBL (drain-induced barrier lowering) and a source-drain punch through, thus increasing an off-state leakage current. Therefore, a performance of the MOSFET may be deteriorated.

Therefore, for a conventional device, large leakage is a main constraint for scaling down.

### SUMMARY OF THE INVENTION

The present disclosure is aimed to solve at least one of the above mentioned technical problems.

According to an aspect of the present disclosure, a semiconductor structure is provided. The semiconductor structure comprises: a wafer; a plurality of convex structures formed on the wafer, in which every two adjacent convex structures are separated by a cavity in a predetermined pattern and arranged in an array, and the cavity between every two adjacent convex structures is less than 50 nm in width; and a first semiconductor film formed on the plurality of convex structures, in which a part of the first semiconductor film on the cavity is floated and spaced apart from the wafer.

In one embodiment, a width of each convex structure increases gradually from a middle part thereof to a top part thereof so that the cavity size between top parts of two adjacent convex structures is less than that between middle parts of the two adjacent convex structures.

In one embodiment, a material forming each convex structure comprises Si, Si₁₋ₓCₓ, Si_{y}Ge_{1-y} or Ge.

In one embodiment, each convex structure comprises a bottom layer and a top layer, the bottom layer is a Si layer, and the top layer is a Si₁₋ₓCₓ layer, a Si_{y}Ge_{1-y}layer, or a Ge layer.

In one embodiment, the first semiconductor film is formed by annealing the plurality of convex structures at a temperature of 300-1350 degrees Celsius in an ambient containing hydrogen.

In one embodiment, the ambient further comprises at least one gas selected from a group consisting of SiH₄, GeH₄, SiH₂Cl₂, and SiHCl₃.

In one embodiment, the first semiconductor film is a Si layer, a Si_{y}Ge_{1-y} layer, or a Ge layer.

In one embodiment, the semiconductor structure further comprises: a first high mobility material layer formed on the first semiconductor film.

According to another aspect of the present disclosure, a method for forming a semiconductor structure is provided. The method comprises steps of: providing a wafer; forming a plurality of convex structures on the wafer, in which every two adjacent convex structures are separated by a cavity in a predetermined pattern and arranged in an array, and the cavity between every two adjacent convex structures is less than 50 nm in width; and forming a first semiconductor film on the plurality of convex structures, in which the first semiconductor film and the wafer are spaced apart by a predetermined height so that a part of the first semiconductor film on the cavity is floated and spaced apart from the wafer.

In one embodiment, a width of each convex structure increases gradually from a middle part thereof to a top part thereof so that the cavity size between top parts of two adjacent convex structures is less than that between middle parts of the two adjacent convex structures.

In one embodiment, a material forming each convex structure comprises Si, Si₁₋ₓCₓ, Si_{y}Ge_{1-y} or Ge.

In one embodiment, each convex structure comprises a bottom layer and a top layer, the bottom layer is a Si layer, and the top layer is a Si₁₋ₓCₓ layer, a Si_{y}Ge_{1-y} layer, or a Ge layer.

In one embodiment, the method according further comprises: partitioning the wafer into a plurality of first regions and a plurality of second regions according to an inputted layout file; removing the first semiconductor films and the convex structures in the plurality of second regions; and forming a MOS transistor structure in each first region, in which each convex structure in the each first region is a channel of the MOS transistor structure, and the first semiconductor films in the each first region are set as a source region and a drain region of the MOS transistor structure respectively.

In one embodiment, the method further comprises: partitioning the wafer into a plurality of first regions and a plurality of second regions according to an inputted layout file; removing the first semiconductor films and the convex structures in the plurality of second regions; and forming a MOS transistor structure in each first region, in which two adjacent convex structures in the plurality of first regions are set as a source region and a drain region of the MOS transistor structure respectively, and the first semiconductor film between the two adjacent convex structures is a channel of the MOS transistor structure respectively.

In one embodiment, the step of forming a first semiconductor film on the plurality of convex structures comprises: annealing the wafer and the plurality of convex structures at a temperature of 300-1350 degrees Celsius in an ambient containing hydrogen.

In one embodiment, the ambient further comprises at least one gas selected from a group consisting of SiH₄, GeH₄, SiH₂Cl₂, and SiHCl₃.

In one embodiment, the method further comprises: forming a first high mobility material layer on the first semiconductor film.

In one embodiment, the step of forming a first semiconductor film on the plurality of convex structures comprises: forming the first semiconductor film on the plurality of convex structures by epitaxy.

In one embodiment, the step of forming a plurality of convex structures on the wafer comprises: forming a second material layer on the wafer; implanting Si or Ge ions into the second material layer to form an ion-implanted layer in the second material layer; and selectively etching the second material layer to form the plurality of convex structures.

With a device formed by the semiconductor structure according to an embodiment of the present disclosure, because the first semiconductor film is spaced apart from the wafer, a leakage current is depressed, and consequently the semiconductor structure according to an embodiment of the present disclosure may inhibit a generation of the leakage current. Moreover, with the semiconductor structure according to an embodiment of the present disclosure, a high mobility channel layer, for example, a Si₁₋ₓCₓ layer, a SiGe layer with high Ge content, a Ge layer, or an III-V group compound semiconductor layer, may be formed, thus improving a performance of a device.

In one embodiment, the floated part of the first semiconductor film is used as a source region and a drain region of a MOS transistor structure respectively, and a channel of the MOS transistor structure is set on the top of the convex structure. In this way, on one hand, dopants in the source and the drain of the MOS transistor structure may be prevented from diffusing into a substrate, so that it may be easy to fabricate an ultra-shallow junction. On the other hand, the source and the drain of the MOS transistor structure may not contact the substrate, thus inhibiting band-to-band tunneling (BTBT) leakage between the source and the drain of the MOS transistor structure and the substrate. Furthermore, parasitic junction capacitance of the source and the drain of the MOS transistor structure maybe reduced, thus improving the performance of the device.

In addition, in another embodiment, the floated part of the first semiconductor film is used as a channel of a MOS transistor structure, and a source region and a drain region of the MOS transistor structure is set on top of two adjacent convex structures respectively. In this way, dopants in the source and the drain of the MOS transistor structure may be prevented from diffusing into the channel of the MOS transistor structure, so that it may be easy to fabricate an ultra-shallow junction.

Additional aspects and advantages of the embodiments of the present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of the disclosure will become apparent and more readily appreciated from the following descriptions taken in conjunction with the drawings in which:

FIG. 1 is a top view of apart of a semiconductor structure according to an embodiment of the present disclosure;

FIG. 2 is a cross-sectional view of a part of a semiconductor structure according to an embodiment of the present disclosure;

FIG. 3 is a cross-sectional view of a part of a semiconductor structure according to another embodiment of the present disclosure;

FIG. 4 is a cross-sectional view of a semiconductor structure according to an embodiment of the present disclosure;

FIG. 5 is a cross-sectional view of a semiconductor structure according to another embodiment of the present disclosure;

FIG. 6 is a cross-sectional view of a semiconductor structure according to still another embodiment of the present disclosure; and

FIG. 7 is a flow chart of a method for forming a semiconductor structure according to an embodiment of the present disclosure.

### DETAILED DESCRIPTION OF THE INVENTION

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

Various embodiments and examples are provided in the following description to implement different structures of the present disclosure. In order to simplify the present disclosure, certain elements and settings will be described. However, these elements and settings are only examples and are not intended to limit the present disclosure. In addition, reference numerals may be repeated in different examples in the disclosure. This repeating is for the purpose of simplification and clarity and does not refer to relations between different embodiments and/or settings. Furthermore, examples of different processes and materials are provided in the present disclosure. However, it would be appreciated by those skilled in the art that other processes and/or materials may be also applied. Moreover, a structure in which a first feature is “on” a second feature may include an embodiment in which the first feature directly contacts the second feature and may include an embodiment in which an additional feature is prepared between the first feature and the second feature so that the first feature does not directly contact the second feature.

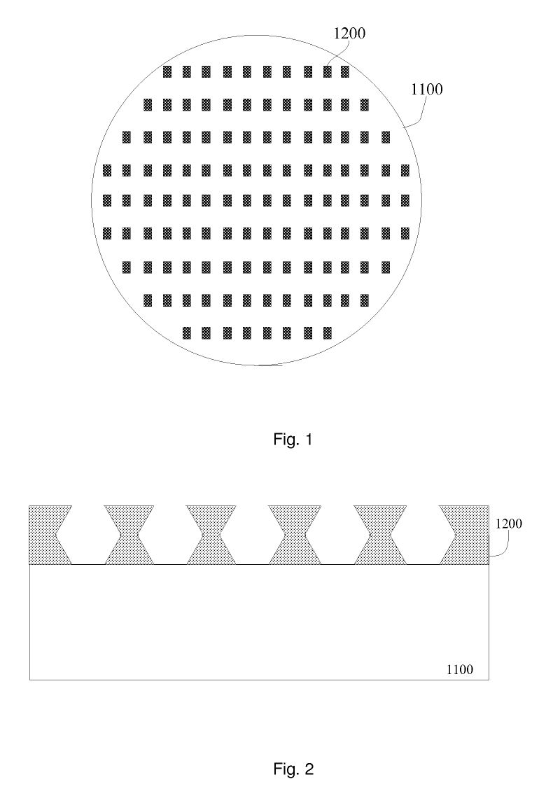

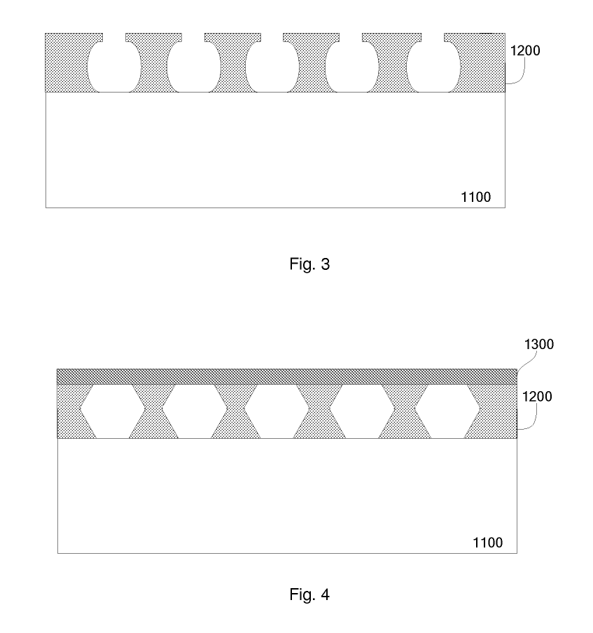

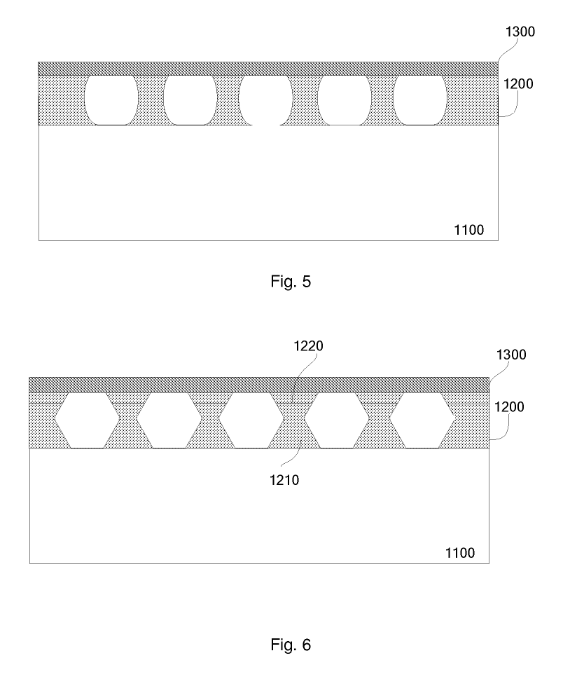

FIG. 1 is a top view of apart of a semiconductor structure according to an embodiment of the present disclosure. FIG. 2 is a cross-sectional view of a part of a semiconductor structure according to an embodiment of the present disclosure. FIG. 3 is a cross-sectional view of a part of a semiconductor structure according to another embodiment of the present disclosure. FIG. 4 is a cross-sectional view of a semiconductor structure according to an embodiment of the present disclosure. FIG. 5 is a cross-sectional view of a semiconductor structure according to another embodiment of the present disclosure.

The semiconductor structure comprises a wafer 1100; a plurality of convex structures 1200 formed on the wafer 1100, in which every two adjacent convex structures 1200 are spaced apart by a cavity in a predetermined pattern and arranged in an array, as shown in FIG. 1. In some embodiments, the cavity between every two adjacent convex structures is less than 50 nm in width, preferably, 30 nm. It should be noted that, in some embodiments, the width of the convex structures 1200 may be fixed in vertical dimension. However, in other embodiments, as shown in FIGS. 2-3, a width of each convex structure 1200 increases gradually from a middle part thereof to a top part thereof so that the cavity size between top parts of two adjacent convex structures 1200 is less than that between middle parts of the two adjacent convex structures 1200. Therefore, a first semiconductor film 1300 may be formed by annealing the convex structures 1200 or by epitaxy. If the cavity size between top parts of two adjacent convex structures 1200 is less than that between middle parts of the two adjacent convex structures 1200, the above-mentioned “less than 50 nm in width” refers to that the top width of the cavity is less than 50 nm. The semiconductor structure according to an embodiment of the present disclosure may be applied to a device with small size, particularly used for alleviating a leakage of a small size device.

The semiconductor structure further comprises a first semiconductor film 1300 formed on the plurality of convex structures 1200, and the first semiconductor film 1300 and the wafer 1100 are spaced apart by a predetermined height. In other words, apart of the first semiconductor film 1300 on the cavity is floated and spaced apart from the wafer 1100. In some embodiments, the predetermined height may be determined according to the available largest etching depth, however, the predetermined height may be any height, provided that the first semiconductor film 1300 may not contact the wafer 1100. In some embodiments, the convex structures 1200 may have various shapes, for example, a cylindrical shape or a cuboid shape, provided that the cavity between two adjacent convex structures 1200 is small enough to form the first semiconductor film 1300 by annealing the convex structures 1200 or by epitaxy. A lateral epitaxial growth rate of the first semiconductor film 1300 with a certain crystal orientation is not less than a longitudinal growth rate thereof, so that a gap between the top parts of two adjacent convex structures 1200 may be quickly sealed up by epitaxial materials. Therefore, the first semiconductor film 1300 may not contact the wafer 1100 directly. In some embodiments, the first semiconductor film 1300 is very thin, and is below about 10nm, and consequently may be used for fabricating an ultra-shallow junction.

In one embodiment, the wafer 1100 is a Si wafer or a SiGe wafer with low Ge content, and the first semiconductor film 1300 is a Si layer, a Si_{y}Ge_{1-y} layer, or a Ge layer. As used herein, the term “a SiGe layer with low Ge content” indicates that a content of Ge in the SiGe layer is lower than 50%, and the term “a SiGe layer with high Ge content” indicates that a content of Ge in the SiGe layer is higher than 50%. In another embodiment, if the first semiconductor film 1300 is formed by epitaxy, the first semiconductor film 1300 may also be a III-V Group compound semiconductor layer.

In one embodiment, a material forming each convex structure 1200 comprises Si, Si₁₋ₓCₓ, Si_{y}Ge_{1-y} or Ge. In some embodiments, the first semiconductor film 1300 may be formed by annealing the wafer 1100 and the plurality of convex structures 1200 or by epitaxy. In some embodiments, the annealing is performed at a temperature of 300-1350 degrees Celsius in an ambient containing hydrogen to migrate atoms on surfaces of the plurality of convex structures 1200. Since the ambient contains hydrogen, a surface of the first semiconductor film 1300 may be activated. Preferably, the ambient further comprises at least one gas selected from a group consisting of SiH₄, GeH₄, SiH₂Cl₂, and SiHCl₃. A small amount of Si and/or Ge atoms are deposited on the surface of the first semiconductor film 1300 by decomposing the at least one gas, so that the surface of the first semiconductor film 1300 may be flattened, and a required flatness is achieved. After the annealing, the top parts of two adjacent convex structures 1200 may be connected with each other to form the first semiconductor film 1300. In this embodiment, the higher the content of Ge in the first semiconductor film 1300, the lower the annealing temperature is. For example, if the first semiconductor film 1300 is a Ge layer, the annealing temperature may be 300 degrees Celsius.

In one embodiment, each convex structure 1200 comprises a bottom layer and a top layer. FIG. 6 is a cross-sectional view of a semiconductor structure according to still another embodiment of the present disclosure. In some embodiments, the bottom layer is a Si layer, and the top layer is a Si₁₋ₓCₓ layer, a Si_{y}Ge_{1-y} layer, or a Ge layer. As shown in FIG. 6, each convex structure 1200 comprises a SiGe layer with low Ge content 1210 and a Ge layer 1220. In this way, the SiGe layer with low Ge content 1210 may be used as a buffer layer between the wafer 1100 and the Ge layer 1220.

In one embodiment, the semiconductor structure further comprises a first high mobility material layer formed on the first semiconductor film 1300.

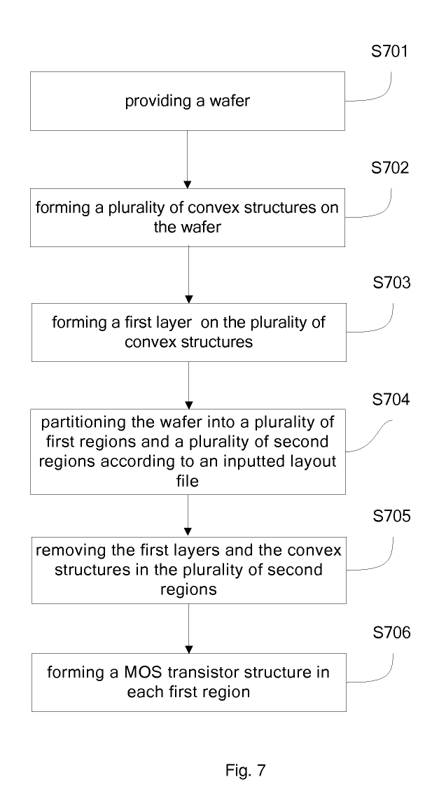

FIG. 7 is a flow chart of a method for forming a semiconductor structure according to an embodiment of the present disclosure. The method comprises the following steps.

Step S701, a wafer is provided. The wafer is a Si wafer, a SOI (silicon on insulator) wafer, or a SiGe wafer with low Ge content.

Step S702, a plurality of convex structures are formed on the wafer, in which every two adjacent convex structures are separated apart by a cavity in a predetermined pattern and arranged in an array. In some embodiments, a cavity between every two adjacent convex structures is less than 50 nm in width, and preferably, 30nm. As shown in FIGS. 2-3, a width of each convex structure increases gradually from a middle part thereof to a top part thereof so that the cavity size between top parts of two adjacent convex structures is less than that between middle parts of the two adjacent convex structures. Therefore, a first semiconductor film may be formed by annealing the convex structures or by epitaxy. In some embodiments, a material forming each convex structure comprises Si, Si₁₋ₓCₓ, Si_{y}Ge_{1-y} or Ge. In one embodiment, each convex structure comprises a bottom layer and a top layer, the bottom layer is a Si layer, and the top layer is a Si₁₋ₓCₓ layer, a Si_{y}Ge_{1-y} layer, or a Ge layer.

In some embodiments, the plurality of convex structures maybe formed by etching. For example, at least one second material layer is formed on the wafer, and then the at least one second material layer is etched to form the plurality of convex structures, in which the at least one second material layer is a Si layer, a SiGe layer or a Ge layer. Certainly, in other embodiments, a surface layer of the wafer is used as the second material layer, that is, a surface of the wafer is directly etched to form the plurality of convex structures.

Preferably, in order to form the plurality of convex structures shown in FIG. 2, the second material layer may be etched by an anisotropic wet etching.

Alternatively, in another preferred embodiment, Si or Ge ions are implanted into the second material layer to form an ion-implanted layer in the second material layer, and then the second material layer is selectively etched by a dry etching to form the plurality of convex structures. Because crystal structures in the ion-implanted layer are damaged seriously, an etching rate in the ion-implanted layer is greater than that in other parts of the second material layer, thus forming the plurality of convex structures shown in FIG. 3.

Step S703, a first semiconductor film is formed on the plurality of convex structures by annealing or epitaxy, and the first semiconductor film and the wafer are spaced apart by a predetermined height. In other words, a part of the first semiconductor film on the cavity is floated and spaced apart from the wafer. In some embodiments, if a first semiconductor film is formed by annealing, the first semiconductor film is a Si layer, a Si_{y}Ge_{1-y} layer, or a Ge layer. In some embodiments, the first semiconductor film may be formed by annealing the wafer and the plurality of convex structures. In some embodiments, the annealing is performed at a temperature of 300-1350 degrees Celsius in an ambient containing hydrogen to migrate atoms on surfaces of the plurality of convex structures. Preferably, the ambient further comprises at least one gas selected from a group consisting of SiH₄, GeH₄, SiH₂Cl₂, and SiHCl₃, so that a surface of the first semiconductor film may be flattened.

In another embodiment, the first semiconductor film may also be formed by epitaxy. In some embodiments, the wafer may be a Si wafer, a Si₁₋ₓCₓ wafer, a SiGe wafer or a Ge wafer with a surface of a crystal orientation (100), in which x is within a range from 0 to 0.1. Because a lateral epitaxial growth rate of the first semiconductor film with a certain crystal orientation is not less than a longitudinal growth rate thereof, a gap between top parts of two adjacent convex structures may be quickly sealed up by epitaxial materials. Therefore, the first semiconductor film may not contact with the wafer directly, so that apart of the first semiconductor film may be spaced apart from the wafer. In some embodiments, the first semiconductor film is very thin, and is below about 10 nm, and consequently may be used for fabricating an ultra-shallow junction. In another embodiment, if the first semiconductor film is formed by epitaxy, the first semiconductor film may also be an III-V group compound semiconductor layer.

In one preferred embodiment, after the annealing or the epitaxy, if the first semiconductor film is thick, the first semiconductor film may be subjected to an etching or a thinning process.

Step S704, the wafer is partitioned into a plurality of first regions and a plurality of second regions according to an inputted layout file, in which a MOS transistor structure will be formed in each first region. In some embodiments, a MOS transistor structure will be formed in each first region, and an interface circuit, an isolation structure, a pad and so on will be formed in each second region.

Step S705, the first semiconductor films and the convex structures in the plurality of second regions are removed.

Step S706, a MOS transistor structure is formed in each first region. In one embodiment, a channel of the MOS transistor structure is set on top of the convex structure in each first region, and the adjacent floated parts of the first semiconductor film in the each first region are set as a source region and a drain region of the MOS transistor structure respectively. In another embodiment, two adjacent convex structures in each first region are set as a source region and a drain region of the MOS transistor structure respectively, and the floated part of the first semiconductor film between the two adjacent convex structures is a channel of the MOS transistor structure. In other embodiments, other similar devices may also be formed.

In one embodiment, the method for forming the semiconductor structure further comprises forming a first high mobility material layer on the first semiconductor film.

It should be noted that, in the above embodiments, the MOS transistor structure is described as an example, however, the semiconductor structure according to an embodiment of the present disclosure may also be applied to other devices.

With a device formed by the semiconductor structure according to an embodiment of the present disclosure, because the first semiconductor film is spaced apart from the wafer, a leakage current is depressed, and consequently the semiconductor structure according to an embodiment of the present disclosure may inhibit a generation of the leakage current. Moreover, with the semiconductor structure according to an embodiment of the present disclosure, a high mobility channel layer, for example, a Si₁₋ₓCₓ layer, a SiGe layer with high Ge content, a Ge layer, or a III-V group compound semiconductor layer, may be formed, thus improving a performance of a device.

In one embodiment, the adjacent floated part of the first semiconductor film is used as a source region and a drain region of a MOS transistor structure respectively, and a channel of the MOS transistor structure is set on the top of the convex structure. In this way, on one hand, dopants in the source and the drain of the MOS transistor structure may be prevented from diffusing into a substrate, so that an ultra-shallow junction may be easy to fabricate. On the other hand, the source and the drain of the MOS transistor structure may not contact with the substrate, thus inhibiting BTBT leakage between the source and the drain of the MOS transistor structure and the substrate. Furthermore, parasitic junction capacitance of the source and the drain of the MOS transistor structure may be reduced, thus improving the performance of the device.

In addition, in another embodiment, the floated part of the first semiconductor film is used as a channel of a MOS transistor structure, and the convex structures are used as a source region and a drain region of the MOS transistor structure respectively. In this way, dopants in the source and the drain of the MOS transistor structure may be prevented from diffusing into the channel of the MOS transistor structure, so that an ultra-shallow junction may be easy to fabricate.

Although explanatory embodiments have been shown and described, it would be appreciated by those skilled in the art that changes, alternatives, and modifications all falling into the scope of the claims and their equivalents may be made in the embodiments without departing from spirit and principles of the disclosure.

What is claimed is:

1. A semiconductor structure, comprising:
a wafer;
a plurality of convex structures formed on the wafer, wherein every two adjacent convex structures are separated by a cavity in a predetermined pattern and arranged in an array, and the cavity between every two adjacent convex structures is less than 50 nm in width; and
a first semiconductor film formed on the plurality of convex structures, wherein a part of the first semiconductor film on the cavity is floated and spaced apart from the wafer.

2. The semiconductor structure according to claim 1, wherein a width of each convex structure increases gradually from a middle part thereof to a top part thereof so that the cavity size between top parts of two adjacent convex structures is less than that between middle parts of the two adjacent convex structures.

3. The semiconductor structure according to claim 1, wherein a material forming each convex structure comprises Si, Si₁₋ₓCₓ, Si_{y}Ge_{1-y} or Ge.

4. The semiconductor structure according to claim 1, wherein each convex structure comprises a bottom layer and a top layer, the bottom layer is a Si layer, and the top layer is a Si₁₋ₓCₓ layer, a Si_{y}Ge_{1-y} layer, or a Ge layer.

5. The semiconductor structure according to claim 1, wherein the first semiconductor film is formed by annealing the plurality of convex structures at a temperature of 300-1350 degrees Celsius in an ambient containing hydrogen.

6. The semiconductor structure according to claim 5, wherein the ambient further comprises at least one gas selected from a group consisting of SiH₄, GeH₄, SiH₂Cl₂, and SiHCl₃.

7. The semiconductor structure according to claim 1, wherein the first semiconductor film is a Si layer, a Si_{y}Ge_{1-y} layer, or a Ge layer.

8. The semiconductor structure according to claim 1, further comprising:
a first high mobility material layer formed on the first semiconductor film.

9. A method for forming a semiconductor structure, comprising steps of:
providing a wafer;
forming a plurality of convex structures on the wafer, wherein every two adjacent convex structures are separated by a cavity in a predetermined pattern and arranged in an array, and the cavity between every two adjacent convex structures is less than 50 nm in width; and
forming a first semiconductor film on the plurality of convex structures, wherein a part of the first semiconductor film on the cavity is floated and spaced apart from the wafer.

10. The method according to claim 9, wherein a width of each convex structure increases gradually from a middle part thereof to a top part thereof so that the cavity size between top parts of two adjacent convex structures is less than that between middle parts of the two adjacent convex structures.

11. The method according to claim 9, wherein a material forming each convex structure comprises Si, Si₁₋ₓCₓ, Si_{y}Ge_{1-y} or Ge.

12. The method according to claim 9, wherein each convex structure comprises a bottom layer and a top layer, the bottom layer is a Si layer, and the top layer is a Si₁₋ₓCₓ layer, a Si_{y}Ge_{1-y} layer, or a Ge layer.

13. The method according to claim 9, further comprising:
partitioning the wafer into a plurality of first regions and a plurality of second regions according to an inputted layout file;
removing the first semiconductor films and the convex structures in the plurality of second regions; and
forming a MOS transistor structure in each first region, wherein a channel of the MOS transistor structure is set on a top of the convex structure, and a source region and a drain region of the MOS transistor structure are set in the floated part of the first semiconductor film respectively.

14. The method according to claim 9, further comprising:
partitioning the wafer into a plurality of first regions and a plurality of second regions according to an inputted layout file;
removing the first semiconductor films and the convex structures in the plurality of second regions; and
forming a MOS transistor structure in each first region, wherein a source region and a drain region of the MOS transistor structure are set on the top of two adjacent convex structures in the plurality of first regions respectively, and a channel of the MOS transistor structure is set in the floated part of the first semiconductor film between the two adjacent convex structures respectively.

15. The method according to claim 9, wherein the step of forming a first semiconductor film on the plurality of convex structures comprises:
annealing the wafer and the plurality of convex structures at a temperature of 300-1350 degrees Celsius in an ambient containing hydrogen.

16. The method according to claim 15, wherein the ambient further comprises at least one gas selected from a group consisting of SiH₄, GeH₄, SiH₂Cl₂, and SiHCl₃.

17. The method according to claim 9, further comprising:
forming a first high mobility material layer on the first semiconductor film.

18. The method according to claim 9, wherein the step of forming a first semiconductor film on the plurality of convex structures comprises:
forming the first semiconductor film on the plurality of convex structures by epitaxy.

19. The method according to claim 10, wherein the step of forming a plurality of convex structures on the wafer comprises:
forming a second material layer on the wafer;
implanting Si or Ge ions into the second material layer to form an ion-implanted layer in the second material layer; and
selectively etching the second material layer to form the plurality of convex structures.
